(19) United States
(12) Patent Application Publication
(10) Pub. No.: US 2011/0139242 A1
(43) Pub. Date: Jun. 16, 2011

(54) LIGHT CONDENSING LENS, MODULE, AND PHOTOELECTRIC TRANSDUCING APPARATUS

(76) Inventor: Yun-Ning Shih, Taipei City (TW)

(21) Appl. No.: 12/780,087

(22) Filed: May 14, 2010

(30) Foreign Application Priority Data
Dec. 11, 2009 (TW) 98223296

(51) Int. Cl. H01L 31/00; G02B 19/00; G02B 17/08

(52) U.S. Cl. 136/259; 359/642; 359/726; 359/730

(57) ABSTRACT

Light condensing lens, module, and photoelectric transducing apparatus are disclosed. The lens has a light receiving surface, a bottom surface, and two side surfaces. The side surfaces are obliquely connected with the light receiving surface and the bottom surface. By designing the radian of the light receiving surface, the light streams can be condensed to a predetermined region no matter where the light source is. Additionally, an auxiliary light module is provided for reflecting the light streams to the predetermined region, in order to increase the photoelectric transducing efficiency.

### BACKGROUND OF THE INVENTION

1. Field of the Invention

The present invention relates to a light condensing lens, especially to a location-fixed light condensing lens, and the associating light condensing module and photoelectric transducing apparatus.

2. Description of the Related Art

Recently, people pay more and more attentions to environmental protection issues, and the using of various of renewable energies, such as solar energy, wind power, tidal power, and geothermal power, are of the most important part. In which the solar energy is almost inexhaustible, and causes no environmental pollution while being generated, so the solar energy indeed plays a decisive role in renewable energies.

Photoelectric transducing module for generating electrical energy from solar energy includes several types, such as silicon semiconductor solar cell, thin film solar cell, and III-V group compound solar cell, etc. In which the silicon semiconductor solar cell and thin film solar cell have low transducing efficiency (only about 15%), and they work properly only when the solar light casts directly onto the solar cells.

And the III-V compound solar cells have high temperature resistant characteristics, and are commonly used in concentrated photovoltaic (CPV) techniques. A light sensor and tracking system is embedded with the solar cell, for tracking lights and extending the time of direct exposure, so as to increase the efficiency of solar cell. However, the light sensor and tracking system also increase the cost of setting up the solar cells, and they are hardly affordable to common people.

### SUMMARY OF THE INVENTION

The present invention provides a light condensing module which is location-fixed and can extend the light exposure time of the photoelectric transducing apparatus without adding the light sensor and the tracking system. Therefore, the cost of setting up the photoelectric transducing apparatus decreases, and the energy transducing efficiency and practical value of the photoelectric transducing apparatus can be increased.

For achieving the aforementioned purposes, according to one scheme of the present invention, a light condensing lens is disclosed. The lens associated with a moving light source, for condensing light streams generated by the moving light source to a predetermined region. The lens includes a light receiving surface, a bottom surface, and two side surfaces. The light receiving surface is on the top of the light condensing lens, for refracting the light streams generated by the moving light source; the bottom surface is on the bottom of the light condensing lens; and the two side surfaces are obliquely connected to the light receiving surface and the bottom surface.

Wherein the light receiving surface has a first arc which is parallel to the moving direction of the moving light source, and a second arc which is perpendicular to the moving direction of the moving light source. Specifically, the light receiving angle of the first arc is larger than the second arc. In which, the light streams generated by the moving light source is refracted by the light receiving surface into the light condensing lens, and is condensed to the predetermined region through the bottom surface.

The bottom surface has a first bottom edge, a second bottom edge, a third bottom edge, and a fourth bottom edge. Wherein the first bottom edge is corresponding to the third bottom edge, and the second bottom edge is corresponding to the fourth bottom edge. Specifically, the length of the first bottom edge equals to the length of the third bottom edge, and the length of the second bottom edge equals to the length of the fourth bottom edge. Moreover, the length of the first bottom edge is larger than the length of the second bottom edge. And the first bottom edge and the third bottom edge contact with the two side surfaces respectively, and the second bottom edge and the fourth bottom edge contact with the light receiving surface.

According to another scheme of the present invention, a light condensing module is provided. The module has a light condensing lens and an auxiliary light module. In which the light condensing lens includes a light receiving surface, a bottom surface, and two side surfaces, for condensing light streams generated by the moving light source. The two side surfaces are obliquely connected with the light receiving surface and the bottom surface.

The auxiliary light module is set nearby the predetermined region for generating secondary light streams from the light streams which are not condensed to the predetermined region properly. The secondary light streams are reflected by the auxiliary light module to the predetermined region.

Specifically, the auxiliary light module has a first reflection surface, a second reflection surface, and a third reflection surface. The first reflection surface is set near by the predetermined region, for reflecting the light streams which are not condensed to the predetermined region. The light streams which are reflected by the first reflection surface are called secondary light streams. The second reflection surface is connected with the first reflection surface for reflecting the secondary light streams. And then, the third reflection surface reflects the secondary light streams again, in order to condense the secondary light streams to the predetermined region.

Additionally, a photoelectric transducing module can be placed at the predetermined region, for converting the light energy of the condensed light streams into electrical energy and transmitting the electrical energy to an electrical power storing module. The back-light side of the photoelectric transducing module can further includes a cooling module, for reducing the temperature of the photoelectric transducing module, in order to avoid circuit damage and increase the transducing efficiency.

According to another scheme of the present invention, a photoelectric transducing apparatus is disclosed. The apparatus includes a photoelectric transducing module and a light condensing lens. The light condensing lens has a light receiving surface, a bottom surface, and two side surfaces for condensing the light streams generated by a moving light source to a predetermined region.

The photoelectric transducing module is located at the predetermined region, for converting the light energy of the condensed light streams into electrical energy, and transmitting the electrical energy to an electrical power storing module. The photoelectric transducing module may be a III-V compound solar cell. Furthermore, the back-light side of the photoelectric transducing module may have a cooling module for reducing the temperature of the photoelectric transducing module.

By designing the radians of the surfaces of the light condensing lens, the light streams which are generated by a moving light source can be properly condensed to a predetermined region regardless of the position of the moving light source. Thus, the photoelectric transducing apparatus does not have to embedded with light sensors and tracking systems, for tracking the moving light source, so as to extend the light exposure time. Consequently, according to the present invention, the cost of the photoelectric apparatus can be reduced, and the practical value of the photoelectric transducing apparatus can be improved.

For further understanding of the invention, reference is made to the following detailed description illustrating the embodiments and examples of the invention. The description is only for illustrating the invention, not for limiting the scope of the claim.

### BRIEF DESCRIPTION OF THE DRAWINGS

The drawings included herein provide further understanding of the invention. A brief introduction of the drawings is as follows:

FIG. 1 is a three-dimensional chart of a light condensing module according to an embodiment of the present invention;

FIG. 2 is a sight draft of a light condensing module according to an embodiment of the present invention;

FIG. 3 is a schematic diagram of a light condensing module according to an embodiment of the present invention;

FIG. 4 is a sight draft of a light condensing module according to an embodiment of the present invention;

FIG. 5 is a schematic diagram of light condensing according to an embodiment of the present invention;

FIG. 6 is a schematic diagram of a photoelectric transducing module according to an embodiment of the present invention;

FIG. 7 is a three-dimensional diagram of an auxiliary light module according to an embodiment of the present invention;

FIG. 8 is a light refraction schematic diagram of the light condensing module according to an embodiment of the present invention;

FIG. 9 is a schematic diagram of the photoelectric transducing module according to an embodiment of the present invention;

FIG. 10A is a schematic diagram of light condensing to a photoelectric transducing module according to an embodiment of the present invention;

FIG. 10B is another schematic diagram of light condensing to a photoelectric transducing module according to an embodiment of the present invention; and

FIG. 11 is a schematic diagram of a photoelectric transducing module, an auxiliary light module, and a light condensing module according to an embodiment of the present invention.

### DETAILED DESCRIPTION OF THE PREFERRED EMBODIMENTS

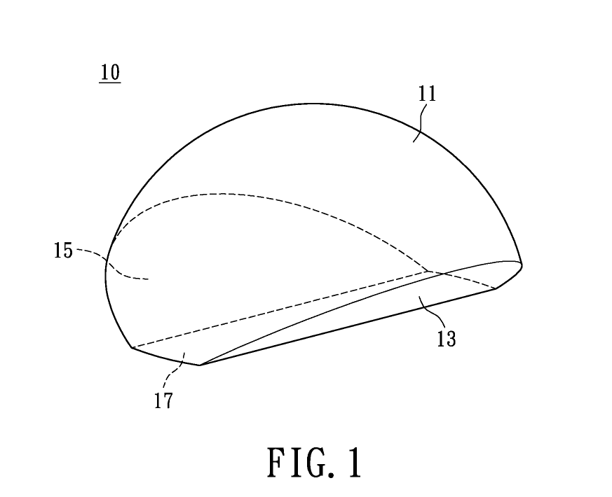

Please refer to FIG. 1, which is a schematic diagram of a light condensing lens 10 according to an embodiment of the present invention. The lens 10 includes a light receiving surface 11, two side surfaces 13 and 15, and a bottom surface 17. Light streams are refracted by the light receiving surface 11 into the lens 10, and are condensed through the bottom surface 17 to a predetermined region. By the designed radian of the light receiving surface 11, the light streams can be condensed to the predetermined region properly.

As shown, the light receiving surface 11 is correspondingly set with the bottom surface 17, and the side surfaces 13 and 15 are obliquely set at opposite sides of the lens 10. In this embodiment, the bottom surface 17 has four edges which are first bottom edge, second bottom edge, third bottom edge, and fourth bottom edge. In which the first bottom edge and the third bottom edge are at opposite sides of the bottom surface 17, and the second bottom edge and the fourth bottom edge are at opposite sides of the bottom surface 17.

Specifically, the first bottom edge and the third bottom edge contact with the side surfaces 13 and 15 respectively, and the second bottom edge and the fourth bottom edge contact with the light receiving surface 11. Moreover, the length of the first bottom edge equals to the length of the third bottom edge, and the length of the second bottom edge equals to the length of the fourth bottom edge. And, the length of the first bottom edge is longer than the length of the third bottom edge.

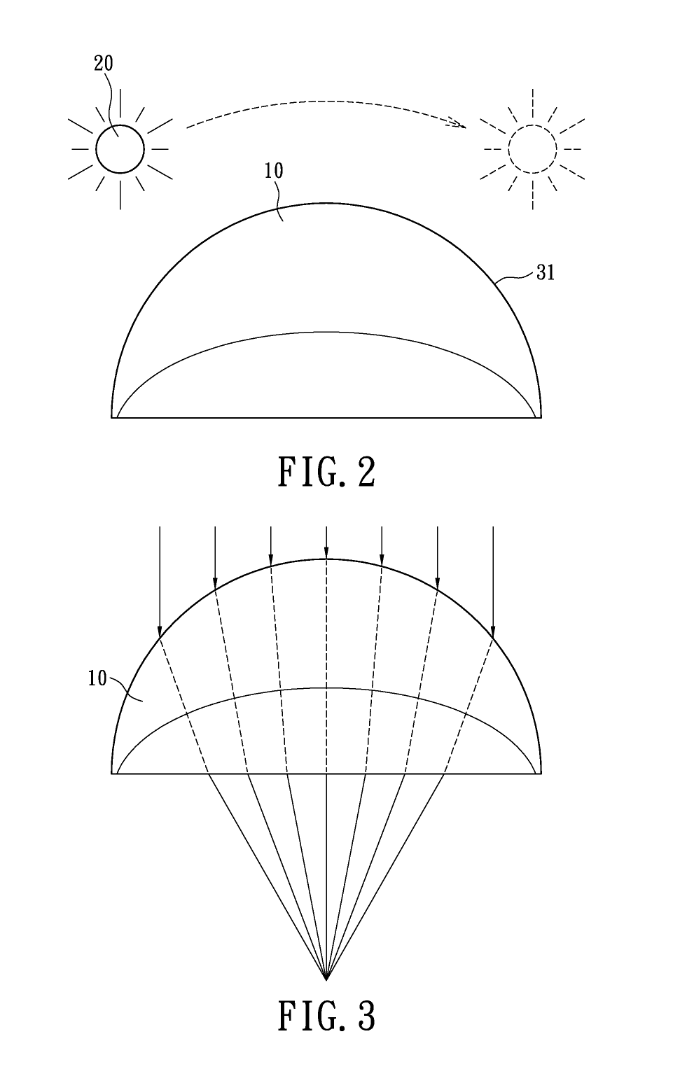

Please refer to FIG. 2, which is a sight draft of the light condensing lens 10 when condensing light. In this embodiment, the moving light source 20 is moving along a fixed direction, and a first arc 31 of the lens 10 is placed parallel to the moving direction of the moving light source 20. In which, the radian of the first arc 31 is designed so that the light condensing lens 10 can be placed at a fixed location for condensing the light streams generated by the moving light source 20 without tracing it, no matter where the light source 20 is. Thus, by designing the radian of the first arc, the light condensing lens 10 can extend the time of condensing light stream to the predetermined region without embedding light sensor and tracking system.

Please refer to FIG. 3, which is a schematic diagram of the light condensing lens 10 when condensing light streams. The light streams are refracted by the light receiving surface 11 and condensed to the predetermined region through the bottom surface 17. The radian of the first arc 31 is designed for condensing light streams which comes from different ways.

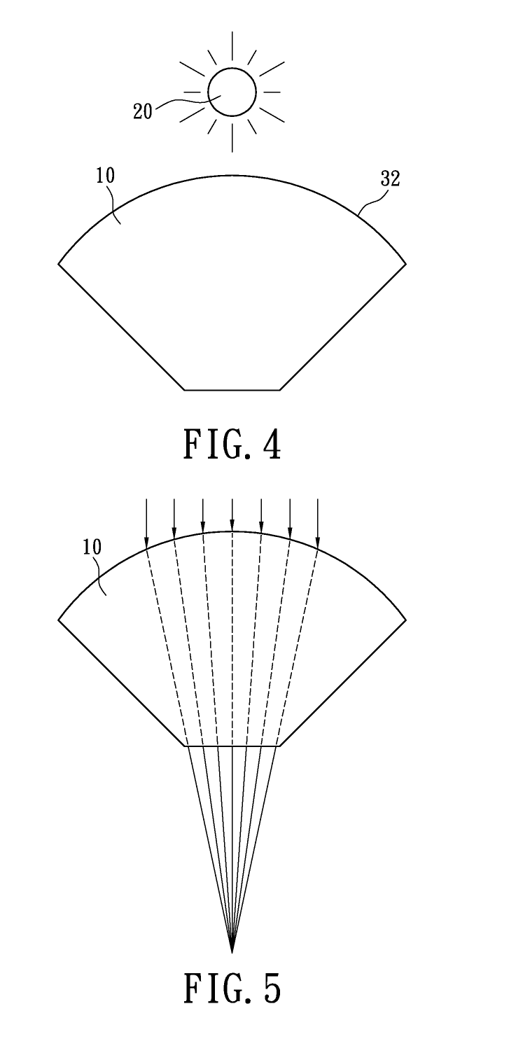

Please refer to FIG. 4, which is a sight chart of the light condensing lens 10. In this embodiment, the second arc 32 of the lens 10 is placed perpendicular to the fixed moving direction of the light source 20. Thus, the length of the second arc 32 would be shorter than the first arc 31. That is, the first light receiving angle of the first arc 31 is greater than the second light receiving angle of the second arc 32.

Specifically, the moving light source 20 can be the sun, and the illuminating angle of the sun would slightly shift in different seasons. Thus the arc length of the second arc 32 may be designed to cover over ninety degree (angular magnitude). Moreover, due to different latitude at different area, the sun may move in an fixed angle. So the lens 10 can be set obliquely right down the sun for better efficiency.

Please refer to FIG. 5, which is a schematic diagram of the light condensing lens when condensing light. As shown, the light streams are refracted by the light receiving surface 11, and are condensed to a predetermined region through the bottom surface 17.

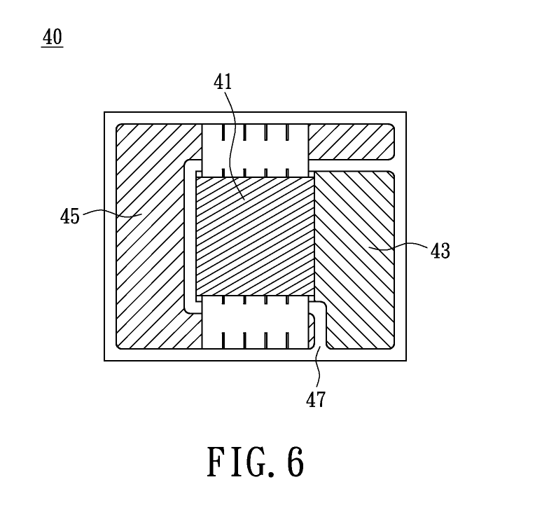

Please refer to FIG. 6, which is a schematic diagram of a photoelectric transducing module 40. The module includes a photoelectric transducing IC 41, positive node 43, negative node 45, and substrate 47.

The photoelectric transducing module 40 is located at the predetermined region for receiving condensed light streams. This can reduce the requisite area of the photoelectric transducing module 40, and reduce the cost of setting up the photoelectric transducing module 40. The photoelectric transducing IC 41 may be a III-V compound solar cell for transducing light energy to electrical power. And the generated electrical power can be outputted through the positive node 43 and the negative node 45 to an electrical power storing module, such as a rechargeable battery.

The substrate 47 can be made of aluminum, for carrying the photoelectric transducing IC 41, the positive node 43, and the negative node 45. And, at the back-light side of the photoelectric transducing module 40 may further include a cooling module. The cooling module can be a metal cooling fin or cooling cream for reducing the temperature of the photoelectric transducing module 40, in order to avoid circuit damage.

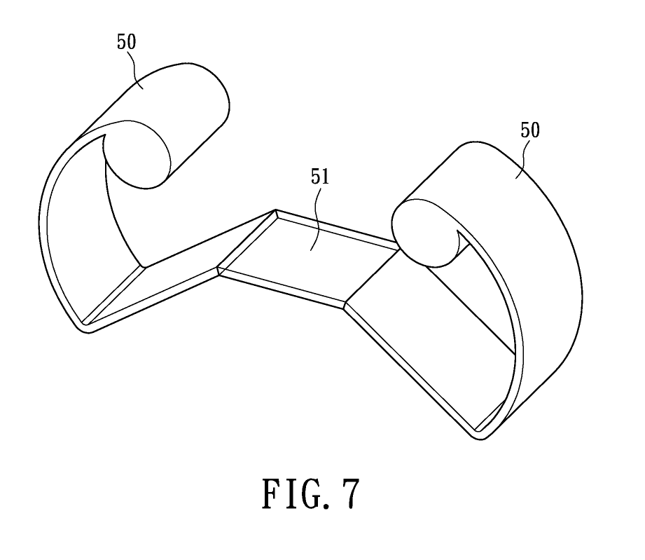

Additionally, the photoelectric transducing module 40 can be embedded with an auxiliary light module 50. The apparatus in FIG. 7 has two symmetrical auxiliary light modules 50. The photoelectric transducing module 40 is placed at the flat area 51, which is the predetermined region for condensing light streams. However, part of the light streams may not be condensed to the predetermined region properly. Thus, the auxiliary light module 50 is needed for reflecting the light streams which are not properly condensed to the predetermined region. The light streams which are reflected by the auxiliary light module 50 are called secondary light streams. By series of reflection, the secondary light streams can be condensed to predetermined region.

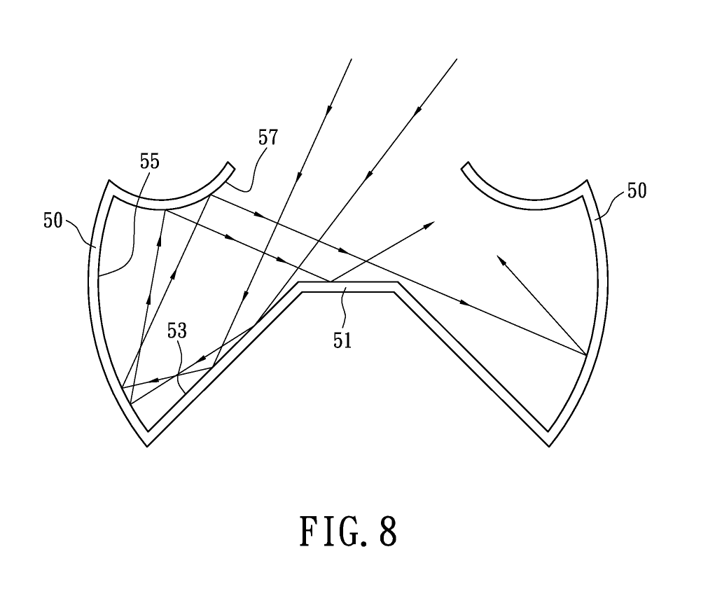

Please refer to FIG. 8, which is a schematic diagram of the auxiliary light module 50 when reflecting the secondary light streams. The light streams which are not properly condensed to the predetermined region are reflected to the second reflection surface 55 by the first reflection surface 53, and then the light streams are reflected to the third reflection surface 57 by the second reflection surface 55. And the third reflection surface 57 reflects the light streams again to the predetermined region (flat area 51). That is, by designing the radian and relative position of the reflection surfaces, the light streams can be properly reflected to the predetermined region.

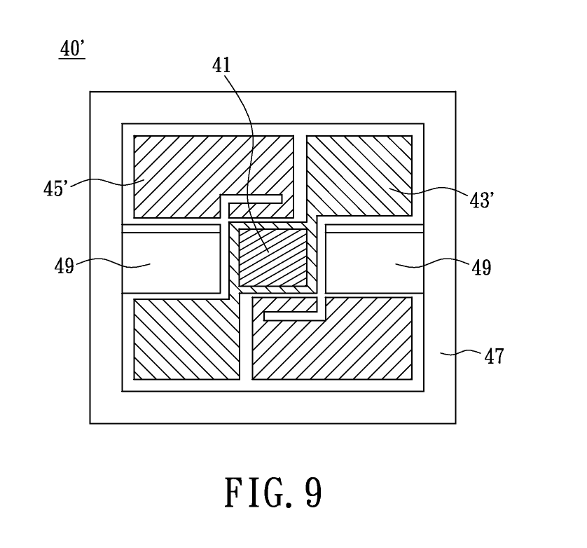

Please refer to FIG. 9, which is a schematic diagram of the photoelectric transducing module 40′ according to another embodiment of the present invention. Similarly, the photoelectric transducing module 40′ has a photoelectric transducing IC 41, positive node 43′, negative node 45′, and substrate 47. The differences between photoelectric transducing module 40′ and 40 are that the module 40′ has cavities around the photoelectric transducing IC 41. In which the cavities are for placing the auxiliary light modules 50.

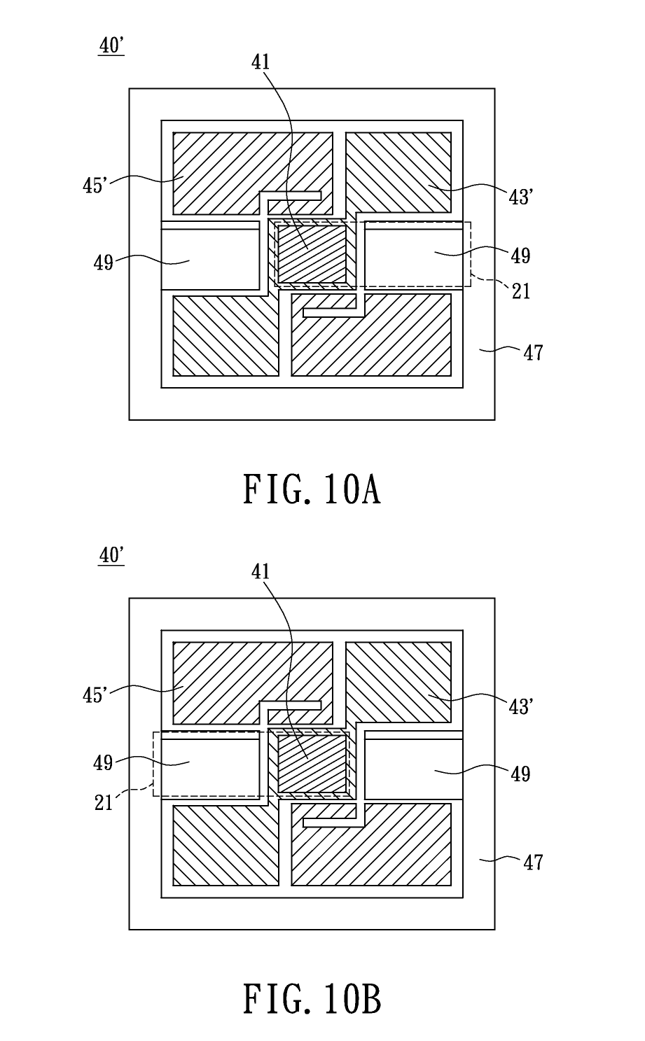

FIGS. 10A and 10B are embodiments of the condensed light. The light streams are condensed to an area 21. The area 21 may slightly shift because of the moving light source 20 (such as the area 21 in FIGS. 10A and 10B). Specifically, the photoelectric transducing IC 41 is place at the overlap portion of the area 21 in FIGS. 10A and 10B.

As shown in FIGS. 10A and 10B, part of the light streams are not condensed onto the photoelectric transducing IC 41. So the auxiliary light module 50 is requisite for reflecting the light streams to the proper place.

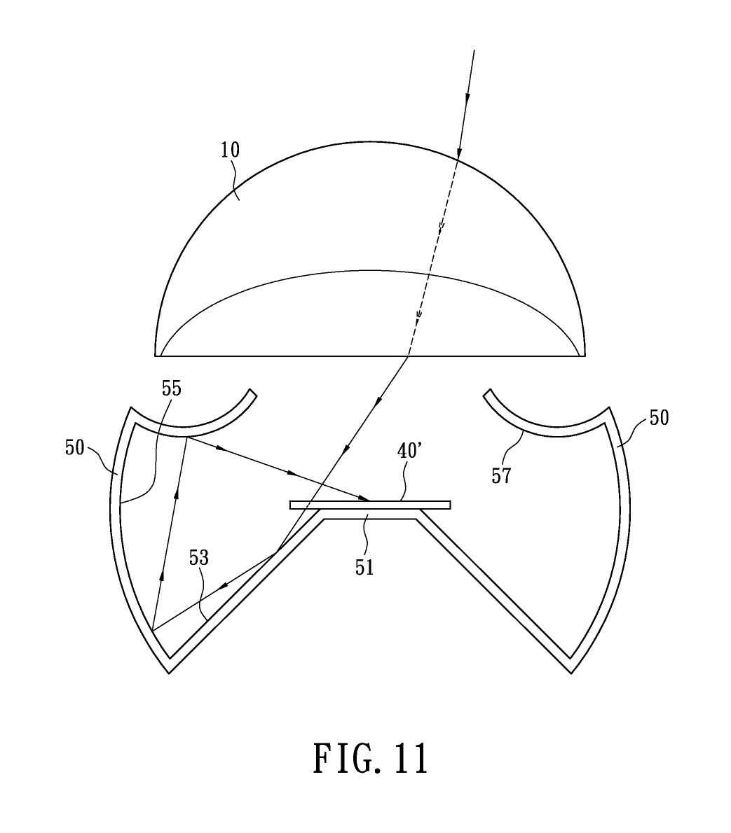

Please refer to FIG. 11, which is a schematic diagram of the light condensing lens 10, the auxiliary light module 50, and the photoelectric transducing module 40′. In which the photoelectric transducing module 40′ is placed at the flat area 51 of the auxiliary light module 50. As shown, the light streams would be condensed toward the flat area 51. However, there still may have some light streams which are not condensed to the flat area 51 properly. The auxiliary light module 50 is for reflecting the light streams to the photoelectric transducing module 40′, in order to increase the efficiency of the photoelectric transducing module 40′.

By providing the light condensing lens and the auxiliary light module, the photoelectric transducing efficiency of photoelectric transducing apparatus can be improved without embedding the light sensor and tracking system. Therefore, the cost of setting up the photoelectric transducing apparatus can be reduced.

Some modifications of these examples, as well as other possibilities will, on reading or having read this description, or having comprehended these examples, will occur to those skilled in the art. Such modifications and variations are comprehended within this invention as described here and claimed below. The description above illustrates only a relative few specific embodiments and examples of the invention. The invention, indeed, does include various modifications and variations made to the structures and operations described herein, which still fall within the scope of the invention as defined in the following claims.

What is claimed is:

1. A light condensing lens associating with a moving light source, for condensing light streams generated by the moving light source, comprising:
a light receiving surface for refracting the light streams into the light condensing lens;
a bottom surface connecting with the light receiving surface; and
two side surfaces obliquely connecting with the light receiving surface and the bottom surface;
wherein the light receiving surface has a first arc which is parallel to a moving direction of the moving light source, and a second arc which is perpendicular to the moving direction of the moving light source; and the light streams is refracted and condensed to a predetermined region by the light receiving surface and the bottom surface.

2. The light condensing lens as in claim 1, wherein the bottom surface includes a first bottom edge, a second bottom edge, a third bottom edge, and a fourth bottom edge, in which the first bottom edge is corresponding to the third bottom edge, and the second bottom edge is corresponding to the fourth bottom edge.

3. The light condensing lens as in claim 2, wherein the length of the first bottom edge equals to the length of the third bottom edge, and the length of the second bottom edge equals to the length of the fourth bottom edge; in which the length of the first bottom edge is longer than the length of the second bottom edge.

4. The light condensing lens as in claim 3, wherein the first bottom edge and the third bottom edge contact with the two side surfaces respectively, and the second bottom edge and the fourth bottom edge contact with the light receiving surface.

5. The light condensing lens as in claim 1, wherein a first light receiving angle of the first arc is larger than a second light receiving angle of the second arc.

6. A light condensing module associating with a moving light source, for condensing light streams generated by the moving light source, comprising:
a light condensing lens having a light receiving surface, a bottom surface, and two side surfaces, for condensing the light streams to a predetermined region, in which the light receiving surface corresponds to the bottom surface, and the two side surfaces obliquely connect with the light receiving surface and the bottom surface; and
at least one auxiliary light module which is set near by the predetermined region, for generating secondary light streams from the light streams which are not properly condensed to the predetermined region, and for reflecting the secondary light streams to the predetermined region;
wherein the light receiving surface has a first arc which is parallel to a moving direction of the moving light source, and a second arc which is perpendicular to the moving direction of the moving light source.

7. The light condensing module as in claim 6, wherein the auxiliary light module comprising:
a first reflection surface set near by the predetermined region, for reflecting the light streams which are not condensed to the predetermined region as the secondary light streams;
a second reflection surface connected with the first reflection surface, for reflecting the secondary light streams; and
a third reflection surface connected with the second reflection surface, for reflecting the secondary light streams again;
wherein first reflection surface, the second reflection surface, and the third reflection surface are vertically set around the predetermined region.

8. The light condensing module as in claim 7, wherein the first reflection surface is a flat surface, and the second reflection surface and the third reflection surface are curved surfaces.

9. The light condensing module as in claim 6, wherein the auxiliary light module is one-piece formed.

10. The light condensing module as in claim 6, further comprising:
a photoelectric transducing module located at the predetermined region, for transducing light energy of the light streams which are condensed to the predetermined region into electrical energy.

11. The light condensing module as in claim 10, wherein the photoelectric transducing module is a III-V compound solar cell.

12. The light condensing module as in claim 10, further comprising:
an electrical power storing module coupled to the photoelectric transducing module, for storing the electrical energy generated by the photoelectric transducing module.

13. The light condensing module as in claim 12, wherein the electrical power storing module is a rechargeable battery.

14. The light condensing module as in claim 10, further comprising:
a cooling module set at a back-light side of the photoelectric transducing module, for reducing a temperature of the photoelectric transducing module.

15. A photoelectric transducing apparatus, comprising:
a light condensing lens having a light receiving surface, a bottom surface, and two side surfaces, for condensing light streams generated by a moving light source to a predetermined region, in which the light receiving surface corresponds to the bottom surface, and the two side surfaces obliquely connect with the light receiving surface and the bottom surface; and
a photoelectric transducing module located at the predetermined region, for converting light energy of the light streams into electrical energy;
wherein the light receiving surface has a first arc which is parallel to a moving direction of the moving light source, and a second arc which is perpendicular to the moving direction of the moving light source.

16. The photoelectric transducing apparatus as in claim 15, wherein the photoelectric transducing module is a III-V compound solar cell.

17. The photoelectric transducing apparatus as in claim 15, further comprising:
an electrical power storing module coupled with the photoelectric transducing module, for storing the electrical energy generated by the photoelectric transducing module.

18. The photoelectric transducing apparatus as in claim 17, wherein the electrical power storing module is a rechargeable battery.

19. The photoelectric transducing apparatus as in claim 15, further comprising:
a cooling module set at non-light-receiving side of the photoelectric transducing module, for reducing a temperature of the photoelectric transducing module.
